(19) United States
(12) Patent Application Publication
(10) Pub. No.: US 2004/0265481 A1
(43) Pub. Date: Dec. 30, 2004

(54) Method for manufacturing electroluminescent element

(76) Inventor: Yoshihiro Kobayashi, Tokyo (JP)

Correspondence Address: SEYFARTH SHAW, 55 EAST MONROE STREET, SUITE 4200, CHICAGO, IL, 60603-5803, US

(21) Appl. No.: 10/607,915

(22) Filed: Jun. 27, 2003

(51) Int. Cl. B05D 5/06

(52) U.S. Cl. 427/66

(57) ABSTRACT

The main object of the present invention is to provide a method for manufacturing an EL element capable of forming thin light emitting layers with an even film thickness at the time of manufacturing an EL element having a plurality of light emitting layers and capable of simplifying the manufacturing process. In order to achieve the above object, the present invention provides A method for manufacturing an electroluminescent element comprising formation of a film of a light emitting layer constituting the electroluminescent element by a printing method, wherein the viscosity of the light emitting layer forming coating solution for forming the light emitting layer is 0.5 cP or more and 500 cP or less.

### BACKGROUND OF THE INVENTION

1. Field of the Invention

The present invention relates to a method for manufacturing an electroluminescent (hereinafter it is also abbreviated as EL) element with a light emitting layer formed as a pattern by a printing method.

2. Description of the Related Art

An EL element couples a hole and an electron, injected from counter electrodes, in a light emitting layer, excites the fluorescent substance in the light emitting layer by the energy, and emits a light of the color corresponding to the fluorescent substance, attracts the attention as a self light emitting flat display element. In particular, an organic thin film EL display using an organic substance as a light emitting material has a high light emitting efficiency and capable of realizing a high luminance light emission even with less than 10 V applied voltage, capable of emitting a light in a simple element structure, and thus application thereof to the advertisement of displaying a specific pattern by light emission and other inexpensive simple displays is expected.

In the manufacturing of the display using such EL element, in general, an electrode layer and an organic EL layer are patterned. As methods for patterning the EL element, a method of deposition of the light emitting material via a shadow mask, a method of divisional coating by ink jetting, or the like can be presented. However, in these methods, there are problems in the aspects of a simple manufacturing process, low efficiency of material utilization, and thinning of films to an optimum film thickness.

In the former deposition method, as the shadowmask pattern gets finer, thinning of the shadowmask is more and more required so that the fine process of the shadow mask is difficult. Furthermore, due to the expand, contract, distortion of the shadow mask, running around of the deposition, or the like, accurate deposition film formation can hardly be achieved, and thus a highly sophisticated vacuum device is essential, and thus it is problematic also in terms of the cost.

Moreover, in the latter ink jet method, application of a pre process onto the structure for supporting patterning or the base material for coating a coating solution is needed, and thus it is problematic in terms of the manufacturing process simplicity.

In particular, these problems cause serious disadvantages in the case of full-colorizing the EL element, that is, when a plurality of colors of the light emitting layers are need to be formed.

### SUMMARY OF THE INVENTION

The present invention has been achieved in view of the above problems, and the main object thereof is to provide a method for manufacturing an EL element capable of forming thin light emitting layers with an even film thickness at the time of manufacturing an EL element having a plurality of light emitting layers, and further, capable of simplifying the manufacturing process.

In order to achieve the above object, the present invention provides a method for manufacturing an electroluminescent element comprising formation of a film of a light emitting layer constituting the electroluminescent element by a printing method, wherein the viscosity of the light emitting layer forming coating solution for forming the light emitting layer is 0.5 cP or more and 500 cP or less. Since the light emitting layer is formed by the printing method, the manufacturing process can be simplified so that the manufacturing efficiency can be improved. Furthermore, by making the viscosity of the light emitting layer forming coating solution in the above range, the coating solution can easily wet and spread on the base material so that thinning of the film thickness of the light emitting layer can be enabled.

In the above mentioned invention, it is preferable that the above mentioned printing method is an intaglio printing. In the intaglio printing, the plate depth is a factor for controlling the film thickness so that thinning of the film thickness of the light emitting layer can be facilitated by adjusting the plate depth.

In the above mentioned invention, it is preferable that the depth of a groove or a cell of the above mentioned intaglio is in a range of 500 Å to 1 mm. In the intaglio printing, the viscosity of the coating solution, the depth of the groove and the cell of the intaglio, or the like are the factors for controlling the film thickness. Therefore, by making the depth of the groove or the cell within the above range, together with the coating solution in the above viscosity range, it is possible to make the film thickness more even and thinner.

In the above mentioned invention, it is preferable that a light emitting layer forming region of the above mentioned intaglio is divided and formed into a plurality of cells.

In the above mentioned invention, it is preferable that the total area of a group of the grooves or the cells on a printing plate is formed smaller than the area of the light emitting layer formed on a base material. Since the total area of the group of the grooves or the cells is formed smaller than the area of the light emitting layer formed on the base material, a light emitting layer having predetermined film thickness and film quality can be formed by wetting and spreading on the base material after the printing operation.

In the above mentioned invention, the above mentioned printing method used is either a method of directly printing the light emitting layer forming coating solution from the printing plate to the base material, or a method of transferring the light emitting layer forming coating solution from the printing plate to a transfer body, and printing the light emitting layer forming coating solution on the transfer body onto the base material. In the present invention, such a method of using a transfer body can be used as well.

In the above mentioned invention, it is preferable that at least one of the printing plate, the transfer body, the base material, or an impression cylinder used in the printing method is an elastic body. At the time of printing from the printing plate to the base material, for example, even when convexo-concave is formed on the base material, since either one of the printing plate or the base material is an elastic body, the printing onto the base material can be enabled, and the it is the same when the transfer body is used.

In the above mentioned invention, divisional coating of two or more colors of the light emitting layer forming coating solutions is possible. By this, manufacturing of the full colored EL element is possible.

In the above mentioned invention, at the time of forming two or more colors of the light emitting layers by the printing method, the coated part is covered with a protective material after solidifying all the light emitting layer forming coating solutions printed preliminarily, and then the subsequent light emitting layer forming coating solution can be printed. By using this method, since the coated part coated preliminarily is covered with the protective layer at the time of coating the subsequent coating solution, the two or more colors of light emitting layer can be patterned without causing a trouble by not damaging the coated part by the printing plate, or the like.

In the above mentioned invention, at the time of forming two or more colors of the light emitting layers by the printing method, the subsequent light emitting layer forming coating solution can be printed before solidifying all the light emitting layer forming coating solutions printed preliminarily. By using this method, since all the coating solutions coated preliminarily are not completely solidified at the time of coating the subsequent coating solution, the two or more colors of light emitting layer can be patterned without damaging the coating solution preliminarily coated by the printing plate, or the like.

According to the present invention, by forming the light emitting layer by the printing method, the manufacturing process can be simplified so as to improve the manufacturing efficiency. Furthermore, by making the viscosity of the light emitting layer forming coating solution within the above mentioned range, the effect of enabling thinning of the light emitting layer film thickness by facilitating wetting and spreading of the coating solution on the base material can be achieved.

### BRIEF DESCRIPTION OF THE DRAWINGS

FIG. 1 is a schematic plan view for explaining a pattern of an intaglio used in the present invention.

FIG. 2 is a schematic side view showing an example of a printing apparatus used in the present invention.

### DESCRIPTION OF THE PREFERRED EMBODIMENTS

The method for manufacturing an EL element according to the present invention comprises formation of a film of a light emitting layer constituting the electroluminescent element by a printing method, wherein the viscosity of the light emitting layer forming coating solution for forming the light emitting layer is 0.5 cP or more and 500 cP or less. It is characteristic of the present invention that the light emitting layer is formed by the printing method, and at the time, the viscosity of the light emitting layer forming coating solution is extremely low as mentioned above, and that an even thin-film like light emitting layer can be formed by wetting and spreading of the coating solution of such a low viscosity. Hereinafter, the manufacturing method of such an EL element of the present invention will be explained specifically.

(Printing Method)

First, the printing method used in the present invention will be explained. In general, as the printing method, depending on the form of the printing plate used, the relief, the intaglio, the surface, the stencil, or the like can be presented. In the present invention, any printing method can be used as long as it is a printing method capable of using a light emitting layer forming coating solution in the above viscosity range. However, since the film thickness of the light emitting layer to be obtained can easily be controlled, it is preferable to use the intaglio printing method using the intaglio. Then, among the intaglio printing methods, in consideration of the accuracy of the light emitting layer to be obtained, it is particularly preferable to use gravure printing.

When the intaglio printing method is used accordingly, in the present invention, it is preferable that the depth of the groove or the cell of the intaglio is in a range of 500 A to 1 mm, in particular, in a range of 500 Å to 500 μm. By making the depth of the groove or the cell of the intaglio in this range, the film thickness of the light emitting layer to be obtained can be optimized.

The shape of the intaglio in the case of printing with the intaglio as mentioned above in the present invention differs drastically, depending on whether a linear pattern is intended to be obtained by the printing plate, or an area-like pattern is intended to be obtained.

For example, when a linear pattern is intended to be obtained, it is preferable that the width of the groove or the cell of the intaglio is in a range of 1 μm to 1 mm, in particular, in a range of 1 μm to 300 μm. By making the width of the groove or the cell of the intaglio in this range, the line width of the pattern of the light emitting layer to be obtained can be adjusted into the demanded line width so that each pattern can be formed densely.

In contrast, when an area-like pattern is intended to be obtained, it is preferable that the width of the groove or the cell of the intaglio is in a range of 1 μm to 1 mm, in particular, in a range of 1 μm to 300 μm. By making the width of the groove or the cell of the intaglio in this range, the area-like pattern can be formed without lacking by making the light emitting layer forming coating solution printed on the base material wet and spread so as to be joined with each other.

Moreover, the interval between the grooves or the cells in the intaglio for obtaining a linear pattern is preferably 1 μm or more. By making the interval between the grooves or the cells of the intaglio in this range, troubles such as color mixture of the light emitting layer formed as a pattern can be avoided.

In contrast, when an area-like pattern is intended to be formed, it is preferable that the interval between the grooves or the cells of the intaglio is in a range of 1 μm to 10 mm, in particular, in a range of 1 82 m to 1 mm. By making the interval between the grooves or the cells of the intaglio in the above range, the area-like pattern can be formed without lacking by allowing the printed light emitting layer forming coating solution wetting and spreading so as to be joined with each other.

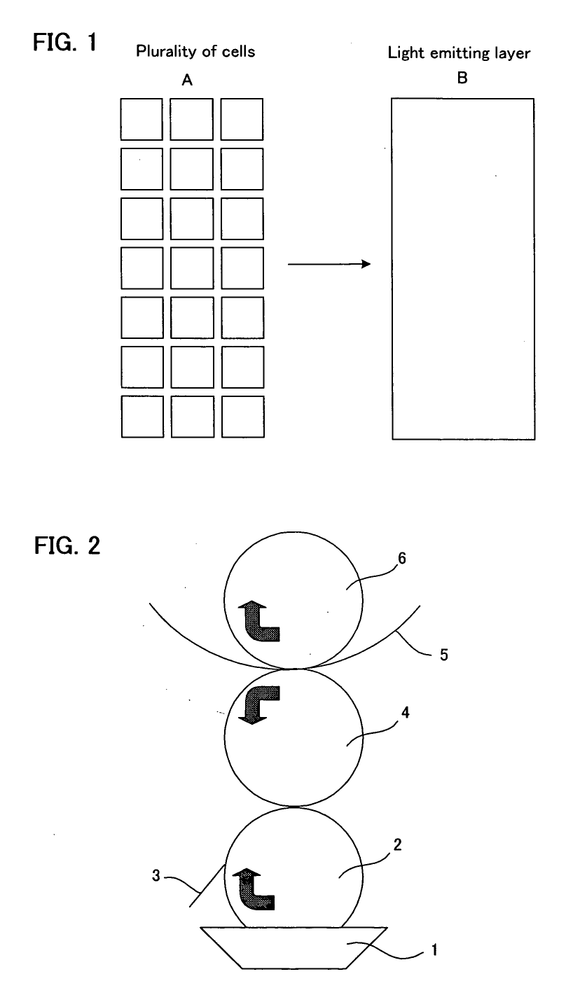

In the present invention, as shown in FIG. 1, it is preferable that the light emitting layer forming region of the intaglio corresponding to the light emitting layer to be formed on the base material is divided and formed into a plurality of cells. That is, it is preferable to form a light emitting layer on the base material as shown in FIG. 1B by using patterns on the printing plate as shown in FIG. 1A.

Moreover, in the present invention, it is preferable that the total area of the group of the grooves or the cells on the above printing plate is formed smaller than the area of the light emitting layer formed on the base material. By accordingly forming the total area of the group of the grooves or the cells smaller than the area of the light emitting layer formed on the base material, a light emitting layer having predetermined film thickness and film quality can be formed by wetting and spreading on the base material after printing.

At the time, with the premise that the area of the light emitting layer formed on the base material is 100, it is preferable that the total area of the group of the grooves or the cells on the printing plate is in a range of 10 to 98, in particular, in a range of 30 to 98.

The shape of the cell in the printing plate used in the present invention is not particularly limited, and a quadrilateral shape, a triangular shape, a pentagonal shape, a hexagonal shape, a circular shape, a semi circular shape, an oblique line plate, or the like can be used.

As to the plate manufacturing method of the printing plate, any method of the conventional gravure, the net gravure, the electronic engraving gravure, or the mill can be used.

The printing method in the present invention may be a method of directly printing the light emitting layer forming coating solution from the printing plate to the base material, or a method of transferring the light emitting layer forming coating solution from the printing plate to a transfer body, and printing the light emitting layer forming coating solution on the transfer body onto the base material. The transfer body used at the time may either be plate-like or cylindrical.

Furthermore, in the printing method used in the present invention, it is preferable that at least one of the printing plate, the base material as a body to be printed, the transfer body, or an impression cylinder is an elastic body. In the case of forming a film of the light emitting layer by the printing method, the light emitting layer is printed often in a state with the layers such as an electrode layer or an insulating layer formed on the base material. At the time of printing in the state, if neither of the printing plate nor the base material has the elasticity, the ruggedness on the base material cannot be dealt with, so that a preferable accurate printing cannot be conducted.

As mentioned above, in the present invention, not only the method of directly printing from the printing plate to the base material, but also the method of printing from the printing plate via the transfer body to the base material is included. In this case, it is preferable that at least one of the printing plate, the base material as the body to be printed, the transfer body, or an impression cylinder is an elastic body.

Here, the elastic body in the present invention refers to those having 10° to 90° hardness based on the JIS standard (JIS A).

When the printing plate, the impression cylinder or the transfer body is an elastic body, a printing plate, an impression cylinder or a transfer body made of a material having the above mentioned elasticity, for example, one prepared by adding a filler or a plasticizing agent to a synthetic rubber (such as an acrylonitrile butadiene rubber), or the like can be used.

In contrast, when the base material is an elastic body, a base material made of a resin can be presented. As the resin which can be used at the time, for example, a polyethylene terephthalate (PET), or the like can be presented.

In the present invention, the printing plate, the transfer body, and the impression cylinder may either be roll-like or plate-like as long as the printing method using the light emitting layer forming coating solution in the above mentioned viscosity range can be conducted. Furthermore, as to the base material, a printing operation can be conducted by using a sheet-like base material wrapped around a roll-like supporting body.

FIG. 2 shows an example of a system of a printing machine usable in the present invention. First, a roll-like plate body 2 is located at a position which a part thereof is soaked in an ink pan 1 which is a coating solution supplying part.

The plate body 2 may either be roll-like or plate-like as mentioned above. Specifically, a metal roll, a rubber roll, or the like can be presented. As the material for forming the same, a synthetic rubber (such as an acrylonitrile butadiene rubber), a ceramic, an ebonite, a conductive material, or the like can be presented.

The part of the plate other then the grooves or the cells may be water repellent. Thereby, elimination of the coating solution by a doctor blade can be facilitated.

In the plate body 2, a doctor blade 3 for eliminating the excessive coating solution is located. As the material for the doctor blade 3, a stainless steel, a synthetic rubber (such as an acrylonitrile butadiene rubber), a ceramic, an ebonite, a conductive material, or the like can be presented.

The coating solution adhered on the above plate body 2 is transferred onto a transfer body 4 as shown in FIG. 1. The transfer body 4 here denotes a roll-like or plate-like body for printing the coating solution on the plate body 2 onto the base material. For example, a metal roll, a rubber roll, an anilox roll (engraving roll), or the like can be presented.

Then, the coating solution transferred onto the transfer body 4 is printed on the base material 5 as the body to be printed. At the time, the base material 5 is located so as to pass between the transfer body 4 and an impression cylinder 6.

Here, the impression cylinder 6 denotes a roll or plate-like body for pressing the base material against the plate body or the transfer body. For example, a metal roll, a rubber roll, or the like can be presented. As the material thereof, a synthetic rubber (such as an acrylonitrile butadiene rubber), or the like can be presented.

(Light Emitting Layer Forming Coating Solution)

Next, the light emitting layer forming coating solution used in the present invention will be explained. In the present invention, evenness and thinning of the light emitting layer are required. Therefore, the coating solution should have the characteristic of thinly wetting and spreading easily. Therefore, in order to satisfy the demand, the viscosity of the coating solution should be low.

From this viewpoint, in the present invention, at the time of forming a plurality of light emitting layers by the above mentioned printing method, it is preferable that the viscosity range of each light emitting layer forming coating solution is in a range of 0.5 cP to 500 cP, in particular, in a range of 0.5 cP to 200 cP. When the viscosity of the light emitting layer forming coating solution is lower than the above range, the concentration of the light emitting material to be described later is made lower so that a light emitting layer having an even film thickness cannot be obtained. Moreover, when the viscosity is higher than the above range, an even film thickness may not be ensured due to insufficient wetting and spreading in the coated region, and furthermore, thinning of the light emitting layer may be difficult.

Moreover, in order to spread sufficiently in the coated region for obtaining an even film, at least one of the solvents used in the coating solution has a boiling point in a range of 60° C. to 400° C., preferably 90° C. to 300° C. Thereby, the coating solution can be leveled evenly. As to a low boiling point solvent of 100° C. or less, the coating solution can be leveled evenly in the atmosphere of the solvent. After transferring the coating solution on the base material, and sufficiently leveling, a drying process is conducted.

Moreover, the surface tension of the light emitting layer forming coating solution used in the present invention is preferably in a range of 10 to 70 mN/m. By making within this range, the contact angle with the base material to be described later can be provided in a predetermined range.

The light emitting layer forming coating solution used in the present invention, in general, is constituted with a light emitting material, a solvent and an additive such as a doping agent. Moreover, since the light emitting layers of a plurality of colors are formed, a plurality of kinds of the light emitting layer forming coating solutions is used. Hereinafter, each material constituting these light emitting layer forming coating solutions will be explained.

A. Light Emitting Material

As the light emitting material used in the present invention, a dye based material, a metal complex based material, and a polymer based material can be presented.

1. Dye Based Material

As the dye based material, a cyclopendamine derivative, a tetraphenyl butadiene derivative, a triphenyl amine derivative, an oxadiazol derivative, a pyrazoloquinoline derivative, a distyryl benzene derivative, a distyryl arylene derivative, a sirol derivative, a thiophene ring compound, a pyridine ring compound, a perinone derivative, a perylene derivative, an oligothiophene derivative, a trifumanyl amine derivative, an oxadiazol dimmer, a pyrazoline dimmer, or the like can be presented.

2. Metal Complex Based Material

As the metal complex based material, metal complexes having an Al, a Zn, a Be, or the like, or a rare earth metal such as a Tb, an Eu, or a Dy as a central metal, and an oxadiazol, a thiadiazol, a phenyl pyridine, a phenyl benzoimidazol, a quinoline structure, or the like as a ligand, such as an aluminum quinolynol complex, a benzoquinolynol beryllium complex, a benzoxazol zinc complex, a benzothiazol zinc complex, an azomethyl zinc complex, a porphyrin zinc complex, an europium complex, or the like can be presented.

3. Polymer Based Material

As the polymer based material, a polyparaphenylene vinylene derivative, a polythiophene derivative, a polyparaphenylene derivative, a polysilane derivative, a polyacetylene derivative, or the like, a polyfluorene derivative, a polyvinyl carbazol derivative, the above dyes, a polymer of a metal complex based light emitting material, or the like can be presented.

In the present invention, from the viewpoint of taking advantage that thinning of the light emitting layer is possible by the printing method using the light emitting layer forming coating solution in the above mentioned viscosity range, those using the above polymer based material as the light emitting material are more preferable.

B. Solvent

As s solvent which dissolves or disperses the above light emitting material to provide the light emitting layer forming coating solution, it is not particularly limited as long as it is a solvent capable of dissolving or dispersing the above light emitting material and providing predetermined viscosity, surface tension, contact angle and drying property.

Specifically, water, a DMF, a DMSO, an alcohol, abenzene, a toluene, isomers of a xylene, isomers of a trimethyl benzene, a tetramethyl benzene, a tetraline, a p-cymene, a cumene, an ethyl benzene, isomers of a diethyl benzene, a butyl benzene, a chlorobenzene, isomers of a dichlorobenzene, an anisol, a phenetole, a butylphenyl ether, a tetrahydrofuran, a 2-butanone, a 1,4-dioxane, a diethyl ether, a diisopropyl ether, a diphenyl ether, a dipenzyl ether, an ether based solvent such as a diglyme, a dichloromethane, a 1,1-dichloroethane, a 1,2-dichloroethane, a trichloroethylene, a tetrachloroethylene, a chloroform, a carbon tetrachloride, a chloro based solvent such as a 1-chloronaphthalene, a cyclohexanone, or the like can be presented. Additionally, other solvents capable of satisfying the condition can be used, and a solvent mixture of two or more kinds can be used as well.

In the present invention, the contact angle of the light emitting layer forming coating solution when printing the light emitting layer forming coating solution on the base material (or the transparent electrode layer) is also an important element for obtaining preferable printing. As to the contact angle in this case, for example, in the case of forming a linear light emitting layer by the printing method, it is in a range of 5° to 170°, preferably 5° to 140°, and in the case of forming an area-like light emitting layer, it is 30° or less, and particularly preferably 20° or less.

Such contact angle is determined by the relationship between the material of the base material and the solvent constituting the light emitting layer forming coating solution. In consideration of this point, as the solvent used for the light emitting layer forming coating solution in the present invention, a toluene can be presented in the case of the light emitting layer forming coating solution for forming a linear light emitting layer, and a xylene can be presented in the case of forming an area-like light emitting layer.

C. Additive

To the light emitting layer forming coating solution used in the present invention, in addition to the above light emitting material and solvent, various kinds of additives can be added. For example, a doping material can be added for the purpose of improving the light emitting efficiency in the light emitting layer, changing the light emitting wavelength, or the like. As the doping material, for example, a perylene derivative, a coumarin derivative, a rubrene derivative, a quinacridone derivative, a squarium derivative, porphylene derivative, a styryl based dye, a tetracene derivative, a pyrazoline derivative, a decacyclene, a phenoxazone, or the like can be presented.

Moreover, as needed, an additive capable of adjusting the viscosity, the surface tension, the contact angle or the drying property, or the like of the light emitting layer forming coating solution may be added.

(Light Emitting Layer)

In the present invention, using the above light emitting layer forming coating solution, the light emitting layer is formed by the printing method. The light emitting layer in the present invention may be one kind of the light emitting layer, or the light emitting layers of a plurality of colors can be formed.

In the present invention, the above light emitting layer is formed in a film thickness in a range of 100 Å to 10,000 Å, preferably in a range of 100 Å to 2,000 Å.

Moreover, the above light emitting layer can be formed either linearly or area-like as mentioned above. In the present invention, the linear formation denotes the case of a 300 μm line width or less. In contrast, in the present invention, the area-like formation denotes the case of more than a 300 μm line width.

(EL Element)

It is characteristic of the method for manufacturing an EL element of the present invention that the light emitting layer is formed by using the above light emitting layer forming coating solution by the above printing method. The EL element obtained by the method for manufacturing an EL element of the present invention is constituted from various kinds of organic EL layers, electrodes, or the like, other than these light emitting layers. Hereinafter, these will be explained.

1. Base Material

The EL element obtained by the method for manufacturing an EL element of the present invention has the above light emitting layer, or the like formed on the base material. Such base material is not particularly limited as long as it has high transparency, and thus an inorganic material such as a glass, a transparent resin, or the like can be used.

The above transparent resin is not particularly limited as long as it can be shaped in a film-like form, and a polymer material having high transparency and relatively high solvent resistance and heat resistance is preferable. Moreover, as needed, a base material having a gas barrier property of blocking a gas such as water vapor and an oxygen can be used. Specifically, a fluorine based resin, a polyethylene, a polypropylene, a polyvinyl chloride, a polyvinyl fluoride, a polystyrene, an ABS resin, a polyamide, a polyacetal, a polyester, a polycarbonate, a modified polyphenylene ether, a polysulfone, a polyallylate, a polyether imide, a polyether sulfone, a polyamide imide, a polyimide, a polyphenylene sulfide, a liquid crystalline polyester, a polyethylene terephthalate, a polybutylene terephthalate, a polyethylene naphthalate, a polymicroyxylene dimethylene terephthalate, a polyoxy methylene, a polyether sulfone, a polyether ether ketone, a polyacrylate, an acrylonitrile-styrene resin, a phenol resin, a urea resin, a melamine resin, an unsaturated polyester resin, an epoxy resin, a polyurethane, a silicone resin, an amorphous polyolefin, or the like can be presented. Other polymer materials capable of satisfying the condition can be used, and a copolymer of two or more kinds can be used as well.

In the present invention, in the case of printing with a printing plate or a transfer body, the base material may be required to have the elasticity as mentioned above. As the resins usable at the time, the resins described in the paragraph of the printing method can be presented.

2. Electrode Layer

The EL element obtained in the present invention comprises a first electrode layer formed on the base material, and a second electrode layer formed on the organic El layer such as the above light emitting layer. Such an electrode layer comprises an anode and a cathode, with either one of the anode or the cathode is transparent or translucent. For the anode, a conductive material having a large work function is preferable so as to facilitate injection of holes. Moreover, a plurality of materials can be mixed. In either one of the electrode layers, those having a small resistance as possible are preferable. In general, a metal material is used, but an organic substance or an inorganic compound can be used as well.

As a preferable anode material, for example, an ITO, an indium oxide, and a gold can be presented. As a preferable cathode material, for example, a magnesium alloy (MgAg, or the like), an aluminum alloy (AlLi, AlCa, AlMg, or the like), a metal calcium and a metal having a small work function can be presented.

3. Organic EL Layer Other Than the Light Emitting Layer

In addition to he above light emitting layer, the EL element obtained in the present invention may be provided in a combination with a buffer layer, a hole transporting layer, a hole injection layer, an electron transporting layer, an electron injection layer, or the like, as the organic EL layer.

4. Insulating Layer

In the EL element obtained by the present invention, an insulating layer may be preliminarily provided so as to the light emitting part is an opening part, to cover the patterned edge part of the first electrode layer formed on the base material and the non-light emitting part of the element so as to prevent short circuit at the unnecessary part for the light emission. Accordingly, the defects by the short circuit of the element, or the like can be reduced so as to obtain a stably light emitting element with a long life.

As it is known ordinarily, a pattern can be formed in the insulating layer using for example a UV hardening type resin material, or the like.

(Method for Manufacturing the EL Element)

Finally, the common process flow in the method for manufacturing an EL element of the present invention will be explained.

First, as needed, the insulating layer is formed so as to cover the edge part of the first electrode on the base material with the first electrode layer preliminarily patterned in a predetermined shape. Then, after forming the organic EL layer such as the buffer layer as needed, the light emitting layer forming coating solutions of a plurality of colors are printed by each color by the printing method.

The printing method at the time is not particularly limited as mentioned above, and a printing method using an intaglio can be used preferably. When the intaglio is used accordingly, a printing operation onto the base material is conducted after adhering the light emitting layer forming coating solution of the above viscosity onto the concave part of the plate by dipping, or the like, and scraping off the excessive coating solution by the doctor blade, or the like.

In the present invention, by printing two or more colors of the light emitting layer forming coating solutions which forms the light emitting layer on the base material, divisional coating of two or more colors of the light emitting layer forming coating solutions become possible. Thereby, manufacturing of a full colored EL element can be enabled finally.

In the case of printing the light emitting layer forming coating solutions for forming the two or more colors of light emitting layer continuously, the subsequent printing operation should be conducted without damaging the light emitting layer preliminarily printed. At the time, it is preferable to use the following two methods.

The first method is a method of covering the coated part with a protective material after solidifying all the light emitting layer forming coating solutions printed preliminarily at the time of forming two or more colors of the above light emitting layer by printing method, and printing the subsequent light emitting layer forming coating solution. As the protective material used here, those formed with any material or by any forming method can be used as long as patterning can be conducted so as not to be formed on the region where the subsequent light emitting layer forming coating solution is to be coated.

In the present invention, a method of coating preliminarily, adhering for example a film-like protective material onto the coated part after solidification, and peeling off the same after coating the subsequent light emitting layer forming coating solution or the like can be presented.

The material used for the protective material is not particularly limited as long as it can be formed in a film-like shape, and a polymer material without or relatively small expansion, contraction or distortion is preferable. Specifically, a fluorine based resin, a polyethylene, a polypropylene, a polyvinyl chloride, a polyvinyl fluoride, a polystyrene, an ABS resin, a polyamide, a polyacetal, a polyester, a polycarbonate, a modified polyphenylene ether, a polysulfone, a polyallylate, a polyether imide, a polyether sulfone, a polyamide imide, a polyimide, a polyphenylene sulfide, a liquid crystalline polyester, a polyethylene terephthalate, a polybutylene terephthalate, a polyethylene naphthalate, a polymicroyxylene dimethylene terephthalate, a polyoxymethylene, a polyether sulfone, a polyether ether ketone, a polyacrylate, an acrylonitrile-styrene resin, a phenol resin, a urea resin, a melamine resin, an unsaturated polyester resin, an epoxy resin, a polyurethane, a silicone resin, an amorphous polyolefin, or the like can be presented. Other polymer materials capable of satisfying the condition can be used, and a copolymer of two or more kinds can be used as well.

By using the method, since the coated part preliminarily coated is covered with the protective material at the time of coating the subsequent coating solution, the two or more colors of light emitting layer can be patterned without the troubles without damaging the coated part by the printing plate, or the like.

In contrast, the second method is a method of printing the subsequent coating solution before solidifying all the coating solution printed preliminarily. When the subsequent printing operation is started after completely solidifying the coating solution preliminarily printed, a problem such as peel off of the part contacted with the printing plate may be generated.

In the present invention, “before solidifying the light emitting layer forming coating solution” denotes the state before the drying process, and capable of leveling the coating solution. In contrast, “after solidifying the light emitting layer coating solution” denotes the state after executing the drying process. All the drying processes are conducted after sufficiently leveling the coating solution.

After forming the light emitting layer accordingly, the EL element is completed by forming the second electrode layer so as to cover the displaying region, and finally sealing for moisture prevention.

The present invention is not limited to the above embodiments. The above embodiments are examples, and any one having the substantially same configuration as the technological idea disclosed in the scope of the claims of the present invention and the same effects is included in the technological range of the present invention.

### EXAMPLES

Hereinafter, the present invention will be explained further with reference to the examples.

### Example 1

### Preparation of the Light Emitting Layer Forming Coating Solution

A light emitting layer forming coating solution 1 was prepared by dissolving a polymer fluorescent substance 1 in a xylene, and adjusting the viscosity to 0.5 cP. Furthermore, a light emitting layer forming coating solution 2 was prepared by dissolving a polymer fluorescent substance 2, showing a light emission color different from that of the polymer fluorescent substance 1, in a xylene, and adjusting the viscosity to 0.5 cP. Here, the polymer fluorescent substance 1 denotes a light emitting material made of a polyvinyl carbazol+a coumarin derivative, and the polymer fluorescent substance 2 denotes a light emitting material made of a polyvinyl carbaxol+a perylene derivative.

<Manufacturing of the Element>

Onto an ITO film formed polycarbonate base material of a 150 mm square, 400 μm thickness, and 40 Ω surface resistivity (manufactured by GEOMATEC Co., Ltd.), a polystyrene sulfonate/poly(3,4)ethylene dioxythiophene (PSS/PEDOT) was formed by 100 nm film thickness, as the hole injection layer, using a spin coater. Furthermore, the formed film was dried at 100° C. for one hour under the reduced pressure.

After the drying operation, first the light emitting layer forming coating solution 1 as the light emitting material was formed into a film of 30 mm×60 mm and 100 nm film thickness, by a simple gravure printing machine (GP-10, manufactured by KURABO INDUSTRIES LTD.) using a printing plate of a 1 mm plate groove width, 10 mm bank width, and a 1 mm plate depth by the gravure printing method.

Thereafter, subsequent thereto, the light emitting layer forming coating solution 2 using a light emitting material different from that of the above light emitting layer forming coating solution 1 was formed into a film in the region other than the part coated in the first operation. At the time, the light emitting layer forming coating solution 2 was printed (coated) before completely solidifying the light emitting layer forming coating solution 1.

As a result, a layer showing a different light emission color was coated divisionally on the same 150 mm square ITO formed polycarbonate by 30 mm×60 mm and 100 nm film thickness each.

Furthermore, after drying the light emitting layer divisionally coated film at 80° C. for one hour under the reduced pressure, a calcium was formed into a film of 5 nm as the second electrode layer, and a silver was vacuum deposited thereon by 250 nm so as to manufacture an EL element.

### Example 2

### Preparation of the Light Emitting Layer Forming Coating Solution

A light emitting layer forming coating solution 3 was prepared by dissolving the above polymer fluorescent substance linaxylene, and adjusting the viscosity to 250 cP. Furthermore, a light emitting layer forming coating solution 4 was obtained by dissolving the above polymer fluorescent substance 2 in a xylene, and adjusting the viscosity to 250 cP.

<Manufacturing of the Element>

Onto an ITO film formed polycarbonate base material of a 150 mm square, 400 μm thickness, and 40 Ω surface resistivity (manufactured by GEOMATEC Co., Ltd.), a polystyrene sulfonate/poly(3,4)ethylene dioxythiophene (PSS/PEDOT) was formed into a film of 100 nm, as the hole injection layer, using a spin coater. Furthermore, the formed film was dried at 100° C. for one hour under the reduced pressure.

After drying, first, the light emitting layer forming coating solution 3 as the light emitting material was formed into a film of 30 mm×60 mm and 100 nm film thickness, by a simple gravure printing machine (GP-10, manufactured by KURABO INDUSTRIES LTD.) using a printing plate of a 8 μm plate groove width, 4 μm bank width, and a 2 μm plate depth by the gravure printing method. Then, the above light emitting layer forming coating solution 4 was formed into a film in the region other than the part coated in the first operation. At the time, the light emitting layer forming coating solution 4 was printed before completely solidifying the light emitting layer forming coating solution 3.

As a result, a layer showing a different light emission color was coated divisionally on the same 150 mm square ITO formed polycarbonate by 30 mm×60 mm and 100 nm film thickness each.

Furthermore, after drying the light emitting layer divisionally coated film at 80° C. for one hour under the reduced pressure, a calcium was formed into a film of 5 nm as the second electrode layer, and a silver was vacuum deposited thereon by 250 nm so as to manufacture an EL element.

### Example 3

### Preparation of the Light Emitting Layer Forming Coating Solution

A light emitting layer forming coating solution 5 was obtained by dissolving the above polymer fluorescent substance 1 in axylene, and adjusting the viscosity to 500 cP. Furthermore, a light emitting layer forming coating solution 6 was obtained by dissolving the polymer fluorescent substance 2, showing a light emission color different form that of the polymer fluorescent substance 1, in a xylene, and adjusting the viscosity to 500 cP.

<Manufacturing of the Element>

Onto an ITO film formed polycarbonate base material of a 150 mm square, 400 μm thickness, and 40 Ω surface resistivity (manufactured by GEOMATEC Co., Ltd.), a polystyrene sulfonate/poly(3,4)ethylene dioxythiophene (PSS/PEDOT) was formed into a film of 100 nm, as the hole injection layer, using a spin coater. Furthermore, the formed film was dried at 100° C. for one hour under the reduced pressure. After drying, first, the light emitting layer forming coating solution 51 was formed into a film of 30 mm×60 mm and 100 nm film thickness, by a simple gravure printing machine (GP-10, manufactured by KURABO INDUSTRIES LTD.) using a printing plate of a 5 μm plate groove width, 1 μm bank width, and a 500 Å plate depth by the gravure printing method. Then, the light emitting layer forming coating solution 6 of a light emitting material of a light emission color different form the that of the above light emitting layer forming coating solution 5 was formed into a film in the region other than the part coated in the first operation. As a result, a layer showing a different light emission color was divisionally coated on the same 150 mm square ITO formed polycarbonate by 30 mm×60 mm and 100 nm film thickness each.

Furthermore, after drying the light emitting layer divisionally coated film at 80° C. for one hour under the reduced pressure, a calcium was formed into a film of 5 nm as the second electrode layer, and a silver was vacuum deposited thereon by 250 nm so as to manufacture an EL element.

### Comparative Example 1

### Preparation of the Light Emitting Layer Forming Coating Solution

A light emitting layer forming coating solution 7 was obtained by dissolving the above polymer fluorescent substance 1 in a xylene, and adjusting the viscosity to 0.4 cP.

<Manufacturing of the Element>

Onto an ITO film formed polycarbonate base material of a 150 mm size, 400 μm thickness, and 40 Ω surface resistivity (manufactured by GEOMATEC Co., Ltd.), a polystyrene sulfonate/poly(3,4)ethylene dioxythiophene (PSS/PEDOT) was formed into a film of 100 nm, as the hole injection layer, using a spin coater. Furthermore, the formed film was dried at 100° C. for one hour under the reduced pressure. After drying, first the light emitting layer forming coating solution 7 was formed by a simple gravure printing machine (GP-10, manufactured by KURABO INDUSTRIES LTD.) using a printing plate of a 1 mm plate groove width, 5 mm bank width, and a 2 mm plate depth by the gravure printing method. Since the polymer fluorescent substance amount in the light emitting layer forming coating solution 7 is small, an even light emitting layer film was not obtained.

### Comparative Example 2

### Preparation of the Light Emitting Layer Forming Coating Solution

A light emitting layer forming coating solution 8 was obtained by dissolving the above polymer fluorescent substance 1 in a xylene, and adjusting the viscosity to 550 cP.

<Manufacturing of the Element>

Onto an ITO film formed polycarbonate base material of a 150 mm square, 400 μm thickness, and 40 Ω surface resistivity (manufactured by GEOMATEC Co., Ltd.), a polystyrene sulfonate/poly(3,4)ethylene dioxythiophene (PSS/PEDOT) was formed into a film of 100 nm, as the hole injection layer, using a spin coater. Furthermore, the formed film was dried at 100° C. for one hour under the reduced pressure. After drying, first, the light emitting layer forming coating solution 8 was formed into a film by a simple gravure printing machine (GP-10, manufactured by KURABO INDUSTRIES LTD.) using a printing plate of a 8 μm plate groove width, 1 μm bank width, and a 300 Å plate depth by the gravure printing method. Since the viscosity in the light emitting layer forming coating solution 8 is high, an even light emitting layer film was not obtained.

What is claimed is:

1. A method for manufacturing an electroluminescent element comprising formation of a film of a light emitting layer constituting the electroluminescent element by a printing method, wherein the viscosity of the light emitting layer forming coating solution for forming the light emitting layer is 0.5 cP or more and 500 cP or less.

2. The method for manufacturing an electroluminescent element according to claim 1, wherein the printing method is a printing method using an intaglio.

3. The method for manufacturing an electroluminescent element according to claim 2, wherein the depth of a groove or a cell of the intaglio is in a range of 500 Å to 1 mm.

4. The method for manufacturing an electroluminescent element according to claim 2, wherein a light emitting layer forming region of the intaglio is divided and formed into a plurality of cells.

5. The method for manufacturing an electroluminescent element according to claim 2, wherein the total area of a group of the grooves or the cells on a printing plate is formed smaller than the area of the light emitting layer formed on a base material.

6. The method for manufacturing an electroluminescent element according to claim 1, wherein the printing method is either a method of directly printing the light emitting layer forming coating solution from the printing plate to the base material, or a method of transferring the light emitting layer forming coating solution from the printing plate to a transfer body and printing the light emitting layer forming coating solution on the transfer body onto the base material.

7. The method for manufacturing an electroluminescent element according to claim 2, wherein the printing method is either a method of directly printing the light emitting layer forming coating solution from the printing plate to the base material, or a method of transferring the light emitting layer forming coating solution from the printing plate to a transfer body and printing the light emitting layer forming coating solution on the transfer body onto the base material.

8. The method for manufacturing an electroluminescent element according to claim 1, wherein at least one of the printing plate, the transfer body, the base material, or an impression cylinder used in the printing method is an elastic body.

9. The method for manufacturing an electroluminescent element according to claim 2, wherein at least one of the printing plate, the transfer body, the base material, or an impression cylinder used in the printing method is an elastic body.

10. The method for manufacturing an electroluminescent element according to claim 1, wherein divisional coating of two or more colors of the light emitting layer forming coating solutions is possible.

11. The method for manufacturing an electroluminescent element according to claim 2, wherein divisional coating of two or more colors of the light emitting layer forming coating solutions is possible.

12. The method for manufacturing an electroluminescent element according to claim 10, wherein at the time of forming two or more colors of the light emitting layers by the printing method, the coated part is covered with a protective material after solidifying all the light emitting layer forming coating solutions printed preliminarily, and then the subsequent light emitting layer forming coating solution is printed.

13. The method for manufacturing an electroluminescent element according to claim 11, wherein at the time of forming two or more colors of the light emitting layers by the printing method, the coated part is covered with a protective material after solidifying all the light emitting layer forming coating solutions printed preliminarily, and then the subsequent light emitting layer forming coating solution is printed.

14. The method for manufacturing an electroluminescent element according to claim 10, wherein at the time of forming two or more colors of the light emitting layers by the printing method, the subsequent light emitting layer forming coating solution is printed before solidifying all the light emitting layer forming coating solutions printed preliminarily.

15. The method for manufacturing an electroluminescent element according to claim 11, wherein at the time of forming two or more colors of the light emitting layers by the printing method, the subsequent light emitting layer forming coating solution is printed before solidifying all the light emitting layer forming coating solutions printed preliminarily.
